(19) United States
(12) Patent Application Publication
(10) Pub. No.: US 2025/0221240 A1
(43) Pub. Date: Jul. 3, 2025

(54) LIGHT EMITTING DISPLAY APPARATUS

(71) Applicant: LG Display Co., Ltd., Seoul (KR)

(72) Inventors: HeeJin KIM, Paju-si (KR); HakMin LEE, Paju-si (KR)

(73) Assignee: LG Display Co., Ltd., Seoul (KR)

(21) Appl. No.: 18/781,527

(22) Filed: Jul. 23, 2024

(30) Foreign Application Priority Data
Dec. 28, 2023 (KR) 10-2023-0194569

(51) Int. Cl. H10K 59/80; H10K 102/00

(52) U.S. Cl. CPC H10K 59/80517; H10K 59/80518; H10K 2102/331

(57) ABSTRACT

A light emitting display apparatus can include a first sub-pixel, a second sub-pixel and a third sub-pixel disposed on a substrate, the first, second and third sub-pixels including first, second and third anodes, respectively, a first reflection electrode disposed under the first anode of the first sub-pixel, a second reflection electrode disposed under the second anode of the second sub-pixel, and a third reflection electrode disposed under the third anode of the first sub-pixel. Also, the light emitting display apparatus can further include a nanoparticle layer disposed between the first reflection electrode and the first anode, between the second reflection electrode and the second anode, or between the third reflection electrode and the third anode.

### CROSS-REFERENCE TO RELATED APPLICATIONS

This application claims priority to Korean Patent Application No. 10-2023-0194569 filed in the Republic of Korea, on Dec. 28, 2023, the entirety of which is hereby incorporated by reference into the present application as if fully set forth herein.

### BACKGROUND

### Field of the Invention

The present disclosure relates to a light emitting display apparatus.

### Discussion of the Related Art

Light emitting display apparatuses are mounted on or provided in electronic products such as televisions, monitors, notebook computers, smart phones, tablet computers, electronic pads, wearable devices, watch phones, portable information devices, navigation devices, or vehicle control display devices, etc., to display images. Pixels are provided in a light emitting display panel configuring a light emitting display apparatus, and a light emitting device is provided in each of the pixels.

Light generated by a light emitting device can be output to the outside through a cathode of the light emitting device, but can also be transmitted in the direction of an anode of the light emitting device.

Accordingly, the luminance of light output from the light emitting device can be reduced.

Also, subpixels of one color may be less bright than subpixels of another color.

Thus, there exists a need for improving the luminance of light output from the light emitting device.

Also, there exists a need for being able differently adjust and increase the brightness of different colored subpixels, while also improving manufacturing efficiencies and reducing manufacturing time and costs.

The above-described background is part of the present disclosure to devise the present disclosure or is technical information acquired by a process of devising the present disclosure, but cannot be regarded as the known art disclosed to the general public before the present disclosure is disclosed.

### SUMMARY OF THE DISCLOSURE

Accordingly, the present disclosure is directed to providing a light emitting display apparatus that substantially obviates one or more problems due to limitations and disadvantages of the related art.

An aspect of the present disclosure is directed to providing a light emitting display apparatus in which nanoparticles are provided at a lower end of an anode.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other advantages and in accordance with the purpose of the disclosure, as embodied and broadly described herein, there is provided a light emitting display apparatus comprising a substrate, a planarization layer configured to cover a pixel driving circuit layer provided on the substrate, an insulation layer configured to be provided on the planarization layer, a nanoparticle layer configured to be provided in the insulation layer, and a first anode, a second anode, and a third anode configured to be provided on the insulation layer, in which the nanoparticle layer is provided at a lower end of at least one of the first anode, the second anode, and the third anode.

It is to be understood that both the foregoing general description and the following detailed description of the present disclosure are example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an example diagram illustrating a configuration of a light emitting display apparatus according to an embodiment of the present disclosure;

FIG. 2 is an example diagram illustrating a structure of a pixel applied to a light emitting display apparatus according to an embodiment of the present disclosure;

FIG. 3 is an example diagram illustrating a structure of a control driver applied to a light emitting display apparatus according to an embodiment of the present disclosure;

FIG. 4 is an example diagram illustrating a structure of a gate driver applied to a light emitting display apparatus according to an embodiment of the present disclosure;

FIG. 5 is an example diagram illustrating a structure of a data driver applied to a light emitting display apparatus according to an embodiment of the present disclosure;

FIG. 6 is an example diagram illustrating the amount of reflection according to the amount of nanoparticles applied to a light emitting display apparatus according to an embodiment of the present disclosure;

FIGS. 7 and 8 are example diagrams illustrating cross sections of three pixels applied to a light emitting display apparatus according to embodiments of the present disclosure;

FIGS. 9 to 12 are other example diagrams illustrating cross sections of three pixels applied to a light emitting display apparatus according to embodiments of the present disclosure;

FIG. 13 is an example diagram illustrating a relationship between a position and a reflectance of a green nanoparticle layer applied to a light emitting display apparatus according to an embodiment of the present disclosure; and

FIG. 14 is an example diagram illustrating a relationship between a position and a reflectance of a red nanoparticle layer applied to a light emitting display apparatus according to an embodiment of the present disclosure.

### DETAILED DESCRIPTION OF THE EMBODIMENTS

Reference will now be made in detail to the example embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present disclosure are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a situation that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. can be used. These terms are intended to identify the corresponding elements from the other elements, and basis, order, or number of the corresponding elements should not be limited by these terms. The expression that an element is “connected,” “coupled,” or “adhered” to another element or layer the element or layer cannot only be directly connected or adhered to another element or layer, but also be indirectly connected or adhered to another clement or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Also, the term “can” used herein can include all meanings and definitions of the term “may.”

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, embodiments of the present disclosure will be described in detail with reference to the accompanying drawings.

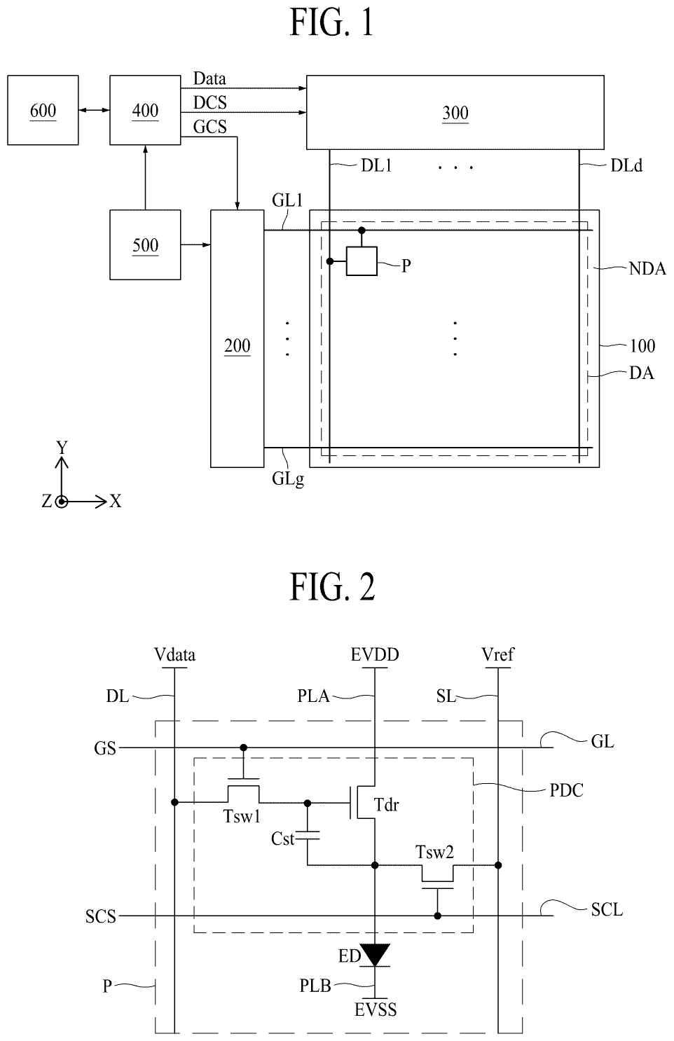

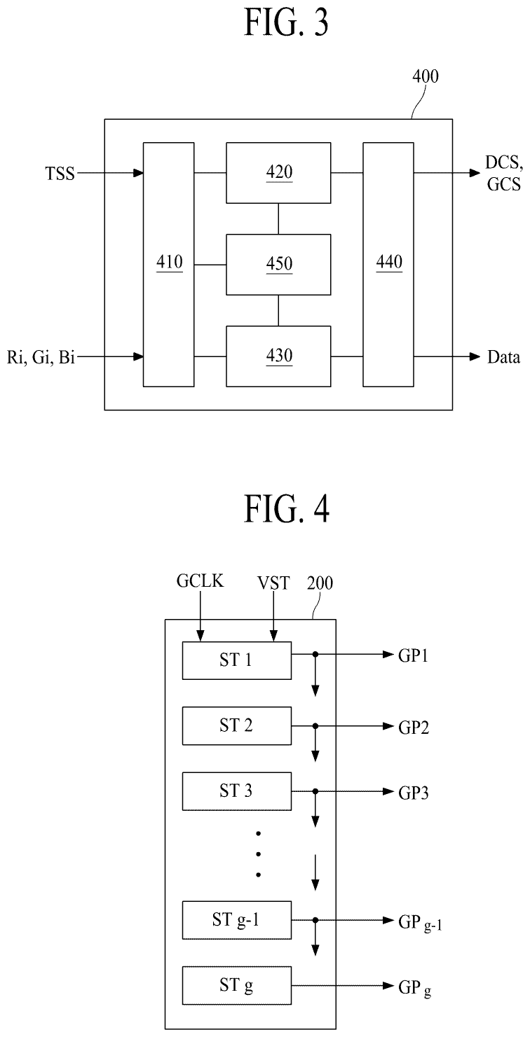

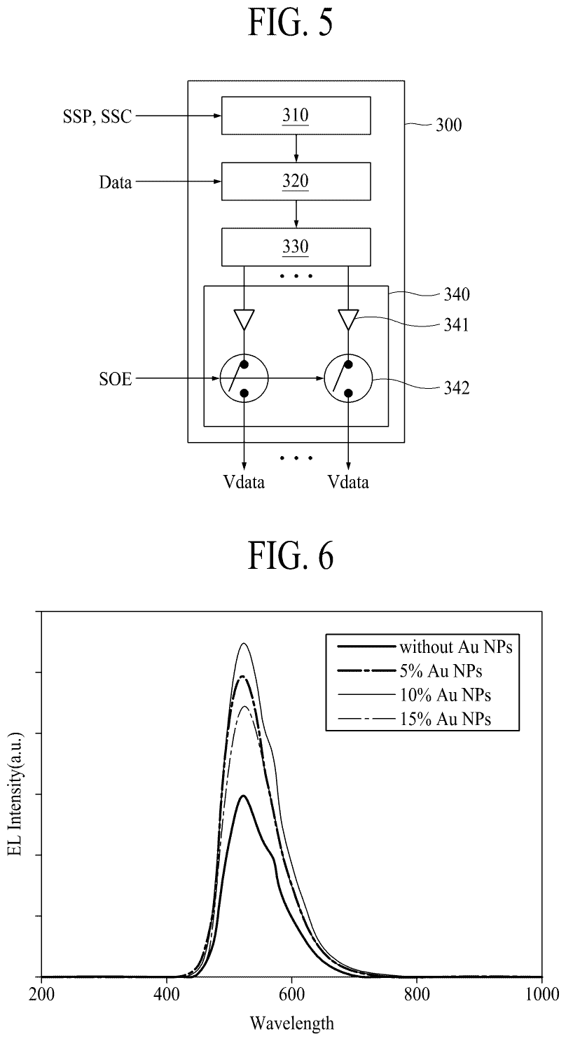

FIG. 1 is an example diagram illustrating a configuration of a light emitting display apparatus according to an embodiment of the present disclosure, FIG. 2 is an example diagram illustrating a structure of a pixel applied to a light emitting display apparatus according to an embodiment of the present disclosure, FIG. 3 is an example diagram illustrating a structure of a control driver applied to a light emitting display apparatus according to an embodiment of the present disclosure, FIG. 4 is an example diagram illustrating a structure of a gate driver applied to a light emitting display apparatus according to an embodiment of the present disclosure, and FIG. 5 is an example diagram illustrating a structure of a data driver applied to a light emitting display apparatus according to an embodiment of the present disclosure.

A light emitting display apparatus according to an embodiment of the present disclosure can be used in various kinds of electronic devices. Electronic devices can be, for example, televisions, monitors, etc.

The light emitting display apparatus according to an embodiment of the present disclosure, as illustrated in FIG. 1, can include a light emitting display panel 100 which includes a display area DA displaying an image and a non-display area NDA provided outside the display area DA, a gate driver 200 which supplies gate signals GS to a plurality of gate lines GL1 to GLg provided in the display area DA of the display panel 100, a data driver 300 which supplies data voltages Vdata to a plurality of data lines DL1 to DLd provided in the display area DA of the display panel 100, a control driver 400 which controls driving of the gate driver 200 and the data driver 300, and a power supply unit 500 which supplies power to the control driver 400, the gate driver 200, the data driver 300, and the light emitting display panel 100.

First, the light emitting display panel 100 can include a display area DA and a non-display area NDA. Gate lines GL1 to GLg, data lines DL1 to DLd, and pixels P can be provided in the display area DA. Accordingly, an image can be displayed in the display area DA. Here, g and d are natural numbers. The non-display area NDA can surround the outer periphery of the display area DA.

The pixel P included in the light emitting display panel 100, as illustrated in FIG. 2, can include a pixel driving circuit PDC which includes a switching transistor Tsw1, a storage capacitor Cst, a driving transistor Tdr, and a sensing transistor Tsw2, and a light emitting device ED connected to the pixel driving circuit PDC.

A first terminal of the driving transistor Tdr can be connected to a first voltage supply line through which a first voltage EVDD is supplied, and a second terminal of the driving transistor Tdr can be connected to the light emitting device ED.

A first terminal of the switching transistor Tsw1 can be connected to a data line DL, a second terminal of the switching transistor Tsw1 can be connected to a gate of the driving transistor Tdr, and a gate of the switching transistor Tsw1 can be connected to a gate line GL.

A data voltage Vdata can be supplied through the data line DL from the data driver 300. A gate signal GS can be supplied through the gate line GL from the gate driver 200. The gate signal GS can include a gate pulse GP for turning on the switching transistor Tsw1 and a gate-off signal for turning off the switching transistor Tsw1.

The sensing transistor Tsw2 can be provided for measuring a threshold voltage of the driving transistor Tdr or mobility of an electrical charge (e.g., an electron), or supplying a reference voltage Vref to the pixel driving circuit PDC. A first terminal of the sensing transistor Tsw2 can be connected to the second terminal of the driving transistor Tdr and the light emitting device ED, a second terminal of the sensing transistor Tsw2 can be connected to a sensing line SL through which the reference voltage Vref is supplied, and a gate of the sensing transistor Tsw2 can be connected to a sensing control line SCL through which a sensing control signal SCS is supplied.

The sensing line SL can be connected to the data driver 300 and can be connected to the power supply unit 500 through the data driver 300. For example, the reference voltage Vref supplied from the power supply unit 500 can be supplied to the pixels through the sensing line SL, sensing signals transmitted from the pixels P can be converted into digital sensing signals in the data driver 300, and the digital sensing signals can be transmitted to the control driver 400.

The light emitting device ED can include a first electrode supplied with a first voltage EVDD through the driving transistor Tdr, a second electrode connected to a second voltage supply line PLB through which a second voltage is supplied, and a light emitting layer provided between the first electrode and the second electrode. The first electrode can be an anode and the second electrode can be a cathode.

The structure of the pixel P applied to a light emitting display apparatus according to an embodiment of the present disclosure is not limited to the structure illustrated in FIG. 2. Accordingly, the structure of the pixel P can be changed to various shapes according to design implementation.

The control driver 400 can realign input image data Ri, Gi, and Bi transmitted from an external system 600 by using a timing synchronization signal TSS transmitted from the external system and can generate a data control signal DCS which is to be supplied to the data driver 300 and a gate control signal GCS which is to be supplied to the gate driver 200.

To this end, as illustrated in FIG. 3, the control driver 400 can include a data aligner 430 which realigns input image data Ri, Gi, and Bi to generate image data Data, a control signal generator 420 which generates the gate control signal GCS and the data control signal DCS by using the timing synchronization signal TSS, an input unit 410 which transmits the timing synchronization signal TSS transmitted from the external system 600 to the control signal generator 420 and transmits the input image data Ri, Gi, and Bi transmitted from the external system 600 to the data aligner 430, and an output unit 440 which supplies the data driver 300 with the image data Data generated by the data aligner 430 and the data control signal DCS generated by the control signal generator 420 and supplies the gate driver 200 with the gate control signal GCS generated by the control signal generator 420.

The control signal generator 420 can generate a power control signal supplied to the power supply unit 500.

The control driver 400 can further include a storage unit for storing various kind of information. The storage unit 450 can be included in the control driver 400 as illustrated in FIG. 3, but can be separated from the control driver 400 and provided independently.

The external system 600 can perform a function of driving the control driver 400 and an electronic device.

For example, when the electronic device is a television (TV), the external system 600 can receive various kinds of sound information, image information, and letter information over a communication network and can transmit the received image information to the control driver 400. For example, the external system 600 can convert the image information into input image data Ri, Gi, and Bi and transmit the input image data Ri, Gi, and Bi to the control driver 400.

The power supply unit 500 can generate various powers and supply the generated powers to the control driver 400, the gate driver 200, the data driver 300, and the light emitting display panel 100.

The gate driver 200 can be directly embedded into the non-display area NDA by using a gate-in panel (GIP) type, or the gate driver 200 can be provided in the display area DA in which light emitting devices ED are provided, or the gate driver 200 can be provided on a chip on film mounted in the non-display area NDA.

The gate driver 200 can supply gate pulses GP1 to GPg to the gate lines GL1 to GLg.

When a gate pulse GP generated by the gate driver 200 is supplied to a gate of the switching transistor Tsw1 included in the pixel P, the switching transistor Tsw1 can be turned on. When the switching transistor Tsw1 is turned on, data voltage Vdata supplied through a data line DL can be supplied to the pixel P.

When a gate-off signal generated by the gate driver 200 is supplied to the switching transistor Tsw1, the switching transistor Tsw1 can be turned off. When the switching transistor Tsw1 is turned off, a data voltage cannot be supplied to the pixel P any longer.

The gate signal GS supplied to the gate line GL can include the gate pulse GP and the gate-off signal.

To supply gate pulses GP1 to GPg to gate lines GL1 to GLg, the gate driver 200, as illustrated in FIG. 4, can include stages ST1 to STg connected to gate lines GL1 to GLg.

Each of the stages ST1 to STg can be connected to one gate line GL, but can be connected to at least two gate lines GL.

In order to generate gate pulses GP1 to GPg, a gate start signal VST and at least one gate clock GCLK which are generated by the control signal generator 420 can be transferred to the gate driver 200. For example, the gate start signal VST and the at least one gate clock GCLK can be included in the gate control signal GCS.

One of the stages ST1 to STg can be driven by a gate start signal VST to output a gate pulse GP to a gate line GL. The gate pulse GP can be generated by a gate clock GCLK.

At least one of signals output from a stage ST where a gate pulse is output can be supplied to another stage ST to drive another stage ST. Accordingly, a gate pulse can be output in another stage ST.

For example, the stages ST can be driven sequentially to sequentially supply the gate pulses GP to the gate lines GL.

The data driver 300 can supply data voltages Vdata to the data lines DL1 to DLd.

To this end, the data driver 300, as illustrated in FIG. 5, can include a shift register 310 which outputs a sampling signal, a latch 320 which latches image data Data received from the control driver 400, a digital-to-analog converter 330 which converts the image data Data, transmitted from the latch 320, into a data voltage Vdata and outputs the data voltage Vdata, and an output buffer 340 which outputs the data voltage, transmitted from the digital-to-analog converter 330, to the data line DL based on a source output enable signal SOE.

The shift register 310 can output the sampling signal by using the data control signal DCS received from the control signal generator 420. For example, the data control signals DCS transmitted to the shift register 310 can include a source start pulse SSP and a source shift clock signal SSC.

The latch 320 can latch image data Data sequentially received from the control driver 400, and then output the image data Data to the digital-to-analog converter 330 at the same time based on the sampling signal.

The digital-to-analog converter 330 can convert the image data Data transmitted from the latch 320 into data voltages Vdata and output the data voltages Vdata.

The output buffer 340 can simultaneously output the data voltages Vdata transmitted from the digital-to-analog converter 330 to data lines DL1 to DLd of the light emitting display panel 100 based on the source output enable signal SOE transmitted from the control signal generator 420.

To this end, the output buffer 340 can include a buffer 341 which stores the data voltage Vdata transmitted from the digital-to-analog converter 330 and a switch 342 which outputs the data voltage Vdata stored in the buffer 341 to the data line DL based on the source output enable signal SOE.

For example, when the switches 342 are turned on based on the source output enable signal SOE simultaneously supplied to the switches 342, the data voltages Vdata stored in the buffers 341 can be supplied to the data lines DL1 to DLd through the switches 342.

The data voltages Vdata supplied to the data lines DL1 to DLd can be supplied to pixels P connected to a gate line GL supplied with a gate pulse GP.

FIG. 6 is an example diagram illustrating the amount of reflection according to the amount of nanoparticles applied to a light emitting display apparatus according to an embodiment of the present disclosure.

A light emitting display apparatus according to an embodiment of the present disclosure uses a metal nanoparticle (hereinafter, simply referred to as a nanoparticle). Metals such as silver (Ag) and gold (Au) can be used as the nanoparticle, but embodiments are not limited thereto.

In particular, a light emitting display apparatus according to an embodiment of the present disclosure uses a plasmon phenomenon generated from nanoparticles.

Plasmon phenomenon refers to a phenomenon in which light reaching a surface of a nanoparticle is amplified and reflected on the surface of the nanoparticle.

Because a resonance wavelength band can be changed according to a diameter of a nanoparticle, the diameter of the nanoparticle can be changed based on a color of a pixel provided with the nanoparticle (e.g., subpixels of different colors can have different sized nanoparticles).

For example, the diameter of a nanoparticle applied to a red pixel can be 50 to 80 nm (e.g., 65 nm), the diameter of a nanoparticle applied to a green pixel can be 10 to 20 nm (e.g., 15 nm), and the diameter of a nanoparticle applied to a blue pixel can be 5 to 10 nm (e.g., 7.5 nm).

According to various tests and simulations, the amount of reflection can be controlled according to the amount of nanoparticles applied to a pixel and the color of light amplified and reflected can be differently controlled by using nanoparticles of different sizes.

For example, as illustrated in FIG. 6, when gold (Au) is used as nanoparticles and nanoparticles are included in a liquid to be injected into a pixel, the amount of reflection when the amount of nanoparticles in the liquid is 15% is lower than the amount of reflection when the amount of nanoparticles in the liquid is 5%.

This means that the reflection amount of nanoparticles is not proportional to the amount of nanoparticles. In other words, simply adding more nanoparticles does not necessarily increase the amount of reflection. For after a certain point, increasing the concentration of nanoparticles can begin to lower the reflectance.

Therefore, the amount of nanoparticles provided in a light emitting display panel can be variously set through various tests and simulations.

To provide an additional description, a resonance wavelength band of a nanoparticle can be determined by a diameter of a nanoparticle, and a reflection amount of a nanoparticle can be determined by the amount of nanoparticles in a liquid containing the nanoparticles.

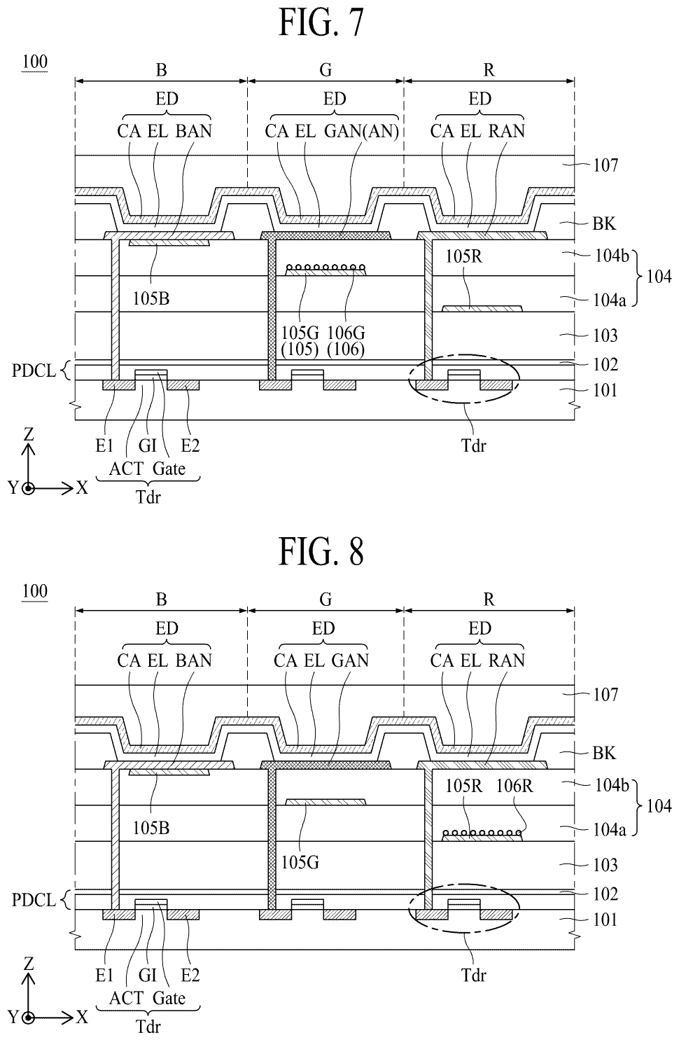

FIGS. 7 and 8 are example diagrams illustrating cross sections of three pixels applied to a light emitting display apparatus according to an embodiment of the present disclosure. In the following descriptions, details which are the same as or similar to details described with reference to FIGS. 1 to 6 are omitted or briefly described.

As illustrated in FIGS. 7 and 8, a light emitting display panel 100 including a substrate 101 provided with a semiconductor can be applied to a light emitting display apparatus according to an embodiment of the present disclosure.

A small light emitting display panel can be applied to a virtual reality (VR) device and an augmented reality (AR) device, e.g., a light emitting display panel 100 including a substrate 101 composed of semiconductors can be applied.

The light emitting device ED provided in the light emitting display panel 100 including the substrate 101 composed of semiconductors can be referred to as Organic Light Emitting Display on Silicon (OLEDOS).

A size of the light emitting display panel applied to virtual reality (VR) devices and augmented reality (AR) devices is much smaller than a size of the light emitting display panel applied to electronic devices such as televisions, monitors, and smartphones.

Therefore, the light emitting display panel applied to virtual reality (VR) devices and augmented reality (AR) devices can be manufactured using a substrate 101 composed of semiconductors, which is advantageous for miniaturization.

For example, the substrate 101 composed of semiconductors can be a silicon substrate formed through a complementary metal oxide semiconductor (CMO) process or a germanium substrate.

In a light emitting display apparatus using a substrate 101 composed of semiconductors, a reflection electrode 105 can be provided at a lower end of an anode AN to increase the extraction efficiency of red light, green light and blue light. For example, reflection electrode 105 can be disposed under an anode AN within a subpixel. Also, depending on the color, the distance at which the reflection electrode 105 is located away from the anode AN can be differently adjusted.

In this situation, light extraction efficiency in each pixel B, G, and R can be increased by adjusting a thickness of an insulator between the anode AN and the reflection electrode 105.

In particular, in a light emitting display apparatus according to one embodiment of the present disclosure, a nanoparticle layer 106 is provided between the reflection electrode 105 and the anode AN to increase the extraction efficiency of red light, green light, and blue light and to increase the amount of light reflected from the reflection electrode 105.

Light generated by the light emitting device ED and transmitted toward the reflection electrode 105 can be reflected by the reflection electrode 105 and the nanoparticle layer 106 and output to the outside through a cathode CA of the light emitting device ED. Accordingly, the luminance of the light output from the light emitting device ED can be increased and power consumption can be reduced.

The above functions can be performed not only in a light emitting display apparatus using a substrate 101 composed of semiconductors, but also in a light emitting display apparatus using a glass substrate, a plastic substrate, or a flexible substrate.

Therefore, a light emitting display apparatus according to an embodiment of the present disclosure can be configured using a substrate 101 composed of semiconductors, or can be configured using a glass substrate, a plastic substrate, or a flexible substrate.

However, in the following, for convenience of description, a light emitting display apparatus using a substrate 101 composed of semiconductors is described as an example of the present disclosure.

A light emitting display panel 100 applied to a light emitting display apparatus according to an embodiment of the present disclosure can include a substrate 101, a pixel driving circuit layer PDCL provided on the substrate 101, a planarization layer 103 covering the pixel driving circuit layer PDCL, an insulation layer 104 provided on the planarization layer 103, a first anode RAN, a second anode GAN, and a third anode BAN which are provided on the insulation layer 104, a bank BK provided between two anodes, a light emitting layer EL covering the first anode RAN, the second anode GAN, the third anode BAN, and the bank, a cathode CA covering the light emitting layer EL, and an encapsulation layer 107 covering the cathode CA. Also, according to an embodiment, the insulation layer 104 can include a plurality of layers.

The first anode RAN can be an anode provided in a pixel which outputs light of one color among red, green, and blue. The second anode GAN can be an anode provided in a pixel which outputs light of one color among red, green, and blue, or can be an anode provided in a pixel which outputs light of a color different from that of the first anode RAN and the third anode BAN. The third anode BAN can be an anode provided in a pixel which outputs light of one color of red, green, and blue, or can be an anode provided in a pixel which outputs light of a color different from that of the first anode RNA and the second anode GAN.

For example, the first anode RAN can be a red anode RAN provided in a red pixel R which outputs red light, the second anode GAN can be a green anode GAN provided in a green pixel G which outputs green light, and the third anode BAN can be a blue anode BAN provided in a blue pixel B which outputs blue light.

However, each of the first anode RAN, the second anode GAN, and the third anode BAN is not limited to an anode used to generate light of one specific color, but can be an anode used to generate any one of various colors.

Hereinafter, for convenience of description, the first anode, the second anode, and the third anode can be described using the reference numerals of the red anode RAN, the green anode GAN, and the blue anode BAN. In particular, a light emitting display apparatus according to an embodiment of the present disclosure is described using the red anode RAN, the green anode GAN, and the blue anode BAN.

However, in the following description, when the red anode RAN or the first anode RAN, the green anode GAN or the second anode GAN, and the blue anode BAN or the third anode BAN need not be distinguished from each other, the red anode RAN or the first anode RAN, the green anode GAN or the second anode BAN, and the blue anode BAN or the third anode BAN can be represented as the anode AN.

First, the substrate 101 can be composed of a semiconductor, as described above, and can be, e.g., a silicon substrate or a germanium substrate.

Next, the pixel driving circuit layer PDCL can be provided on the substrate 101. The pixel driving circuit layer PDCL can include the transistors Tsw1, Tsw2, and Tsdr and the capacitor Cst described with reference to FIG. 2.

That is, the transistors Tsw1, Tsw2, and Tdr and the capacitor Cst described with reference to FIG. 2 can be provided on the substrate 101.

For example, in FIG. 7, a light emitting display panel 100 having only driving transistors Tdr in the pixel driving circuit layer PDCL is illustrated, but in addition to the driving transistor Tdr, various transistors and capacitors can be further provided in the pixel driving circuit layer PDCL.

The pixel driving circuit layer PDCL can include at least one electrode layer and at least one insulation layer.

For example, as illustrated in FIG. 7, when the driving transistor Tdr includes the first electrode E1, the second electrode E2, the active ACT, the gate insulation layer GI, and the gate electrode Gate, the pixel driving circuit layer PDCL can include a first electrode layer provided with the first electrode E1 and the second electrode E2, a second electrode layer provided with the gate electrode Gate, a first insulation layer provided with the gate insulation layer GI, and a second insulation layer provided with a passivation layer 102 covering the driving transistor Tdr.

The first electrode E1 and the second electrode E2 can be formed by implanting impurities into the substrate 101. For example, the first electrode E1 and the second electrode E2 can be formed by implanting N-type impurities such as phosphorus (P) or arsenic (As) into the substrate 101, or by implanting P-type impurities such as boron (B) into the substrate 101.

The active ACT refers to a semiconductor provided between the first electrode E1 and the second electrode E2, and thus a portion of the substrate 101 can be used as the active ACT.

The gate insulation layer GI can be formed of silicon oxide.

The gate electrode Gate can be a doped semiconductor material, or can be a metal material such as aluminum and tungsten.

The passivation layer 102 can cover transistors provided in the pixel driving circuit layer PDCL to protect the transistors. In this situation, various metal lines connected to the pixel driving circuit layer PDCL can be provided at an upper end of the passivation layer 102 or inside the passivation layer 102. To this end, the passivation layer 102 can be formed of at least one layer.

Next, the planarization layer 103 can perform a function of planarizing the upper end of the pixel driving circuit layer PDCL. The planarization layer 103 can be formed of at least one of various types of organic layers, can be formed of at least one of various types of inorganic layers, or can be formed of at least one organic layer and at least one inorganic layer.

Next, the insulation layer 104 can be provided on an upper end of the planarization layer 103. According to embodiments, insulation layer 104 can include one or more layers.

The upper end of the planarization layer 103 and the insulation layer 104 can be provided with a first reflection electrode (or red reflection electrode) 105R corresponding to the first anode (or red anode) RAN, a second reflection electrode (or green reflection electrode) 105G corresponding to the second anode (or green anode) GAN, and a third reflection electrode (or blue reflection electrode) 105B corresponding to the third anode (or blue anode) BAN.

Also, the nanoparticle layer 106 can be provided in the insulation layer 104.

The nanoparticle layer 106 can be provided at a lower end of at least one of the red anode RAN, the green anode GAN, and the blue anode BAN.

Hereinafter, for convenience of description, the first reflection electrode, the second reflection electrode, and the third reflection electrode can be described using the reference numerals of the red reflection electrode 105R, the green reflection electrode 105G, and the blue reflection electrode 105B. In particular, a light emitting display apparatus according to an embodiment of the present disclosure is described using the red reflection electrode 105R, the green reflection electrode 105G, and the blue reflection electrode 105B.

However, in the following description, when the first reflection electrode (or red reflection electrode) 105R, the second reflection electrode (or green reflection electrode) 105G, and the third reflection electrode (or blue reflection electrode) 105B do not need to be distinguished from each other, the first reflection electrode (or red reflection electrode) 105R, the second reflection electrode (or green reflection electrode) 105G, and the third reflection electrode (or blue reflection electrode) 105B can be represented as reflection electrodes 105.

Next, the blue anode BAN, the green anode GAN, and the red anode RAN can be provided on the insulation layer 104 at regular intervals.

Next, the bank BK can be provided between the two anodes AN.

The bank BK covers the ends of the anodes AN, and light can be output to the outside through an area of the anode AN not covered by the bank BK (hereinafter, simply referred to as an opening portion).

The bank BK can be formed of at least one of an organic material and an inorganic material.

Next, the anode AN and the bank BK are covered by the light emitting layer EL.

The light emitting layer EL, as illustrated in FIG. 7, can be provided continuously between the anodes AN (e.g., the light emitting layer EL can extend continuously across subpixels as a common layer), or can be provided independently in each subpixel like the anode AN.

Next, the light emitting layer EL is covered by the cathode CA. For example, the cathode CA can extend continuously across subpixels as a common layer, but embodiments are not limited thereto.

Finally, the encapsulation layer 107 can be provided on the cathode CA. The encapsulation layer 107 can be formed of at least one layer (e.g., multiple layers, such as an organic insulating layer between two inorganic insulating layers, etc.).

Also, a color filter can be provided on the cathode CA. The color filter can be provided on the encapsulation layer 107 or can be provided inside the encapsulation layer 107.

Hereinafter, the structure of the insulation layer 104, the reflection electrodes 105B, 105G, and 105R, and the nanoparticle layer 106 will be described in detail with reference to FIGS. 7 and 8.

First, in a light emitting display apparatus according to an embodiment of the present disclosure, as described above, the insulation layer 104 can be provided on an upper end of the planarization layer 103. The blue reflection electrode 105B, the green reflection electrode 105G, and the red reflection electrode 105R corresponding to the blue anode BAN, the green anode GAN, and the red anode RAN can be provided on an upper end of the planarization layer 103 and in the insulation layer 104. The nanoparticle layer 106 can be provided in the insulation layer 104.

For example, the red reflection electrode 105R is provided at a lower end of the red anode RAN, and the red reflection electrode 105R is provided at an upper end surface of the planarization layer 103. Accordingly, the red anode RAN and the red reflection electrode 105R are separated by the insulation layer 104.

The green reflection electrode 105G is provided at a lower end of the green anode GAN, and the green reflection electrode 105G is provided in the insulation layer 104. In this situation, the green anode GAN and the green reflection electrode 105G are separated through a portion of the insulation layer 104.

The blue reflection electrode 105B can be provided at a lower end of the blue anode BAN, and the blue reflection electrode 105B can be provided on an upper end surface of the insulation layer 104. In this situation, the blue anode BAN can be provided on an upper end surface of the blue reflection electrode 105B. For example, the blue reflection electrode 105B and the blue anode BAN can be sequentially provided on an upper end surface of the insulation layer 104.

In this situation, the nanoparticle layer 106 can be provided at a lower end of at least one of the red anode RAN, the green anode GAN, and the blue anode BAN.

For example, the nanoparticle layer 106 can be provided between at least one of the following pairs: the red anode RAN and the red reflection electrode 105R, the green anode GAN and the green reflection electrode 105G, and the blue anode BAN and the blue reflection electrode 105B.

For example, a light emitting display panel 100 with a green nanoparticle layer 106G between the green anode GAN and the green reflection electrode 105G is illustrated in FIG. 7, and a light emitting display panel 100 with a red nanoparticle layer 106R between the red anode RAN and the red reflection electrode 105R is illustrated in FIG. 8.

In the following description, the green nanoparticle layer is described using a reference numeral 106G, and the red nanoparticle layer is described using a reference numeral 106R. Also, when it is not necessary to distinguish between the green nanoparticle layer 106G and the red nanoparticle layer 106R, the green nanoparticle layer 106G and the red nanoparticle layer 106R can be represented as the nanoparticle layer 106.

The reflection electrode 105 can be provided at a lower end of the anode AN to increase the extraction efficiency of blue light output from the blue pixel B, green light output from the green pixel G, and red light output from the red pixel R.

For example, by forming a microcavity structure between the blue anode BAN and the blue reflection electrode 105B, light output from the light emitting device ED including the blue anode BAN can further include blue light than light of other colors. In this situation, if the light output from the light emitting device ED passes through the blue color filter, only the blue light can be output to the outside through the blue color filter. Accordingly, using the microcavity structure, more blue light can be output to the outside through the blue color filter and luminance can be increased.

Moreover, by forming a microcavity structure between the green anode GAN and the green reflection electrode 105G, more green light can be output to the outside through the green color filter.

Similarly, by forming a microcavity structure between the red anode RAN and the red reflection electrode 105R, more red light can be output to the outside through the red color filter.

To this end, the distance between the red anode RAN and the red reflection electrode 105R, the distance between the green anode GAN and the green reflection electrode 105G, and the distance between the blue anode BAN and the blue reflection electrode 105B can be set differently in order to amplify color of a specific wavelength due to the microcavity effect.

For example, as illustrated in FIGS. 7 and 8, the distance between the red anode RAN and the red reflection electrode 105R can be formed to be greater than the distance between the green anode GAN and the green reflection electrode 105G, and the blue anode BAN can be provided on an upper end surface of the blue reflection electrode 105B.

The distance between the red anode RAN and the red reflection electrode 105R, and the distance between the green anode GAN and the green reflection electrode 105G can be variously set depending on the size of a light emitting display panel 100, the level of power applied to a light emitting device ED, and the size of a light emitting device ED. Accordingly, the distance between the red anode RAN and the red reflection electrode 105R and the distance between the green anode GAN and the green reflection electrode 105G can be variously set through various tests and simulations.

In this situation, according to various tests and simulations, when the blue anode BAN is provided on the upper end surface of the blue reflection electrode 105B, the reflection efficiency of the blue light is the greatest. Therefore, in the following description, as illustrated in FIGS. 7 and 8, a light emitting display panel in which the blue anode BAN is provided on the upper end surface of the blue reflection electrode 105B is described as an example of the light emitting display panel 100 applied to the light emitting display apparatus according to an embodiment of the present disclosure.

The diameter of the nanoparticles included in the red nanoparticle layer 106R provided at a lower end of the red anode RAN, the diameter of the nanoparticles included in the green nanoparticle layer 106G provided at a lower end of the green anode GAN, and the diameter of the nanoparticles included in the blue nanoparticle layer 106B provided at a lower end of the blue anode BAN can be different from each other. In other words, subpixels of different colors can include nanoparticles of different sizes, in order to further amplify light of a specific color for a given subpixel.

Metals such as silver (Ag) and gold (Au) can be used as the nanoparticles, but embodiments are not limited thereto.

A light emitting display apparatus according to an embodiment of the present disclosure can improve light extraction efficiency through a plasmon phenomenon formed on the surface of the nanoparticles. For example, due to the plasmon phenomenon, the reflectance of light incident on the surface of the nanoparticles can increase on the surface of the nanoparticles.

In this situation, the resonance wavelength band can be changed depending on the size of the nanoparticle and different specific colors can be amplified based on the sizing of the nanoparticle.

Therefore, depending on the size of the nanoparticle, the wavelength band of light reflected from the surface of the nanoparticle can vary.

The diameter of the nanoparticles included in the red nanoparticle layer 105R, the diameter of the nanoparticles included in the green nanoparticle layer 105G, and the diameter of the nanoparticles included in the blue nanoparticle layer can be variously set through various tests and simulations.

For example, the diameter of the nanoparticles can be 50 to 80 nm (e.g., 65 nm) in order to increase the reflectance of red light, the diameter of the nanoparticles can be 10 to 20 nm (e.g., 15 nm) in order to increase the reflectance of green light, and the diameter of the nanoparticles can be 5 to 10 nm (e.g., 7.5 nm) in order to increase the reflectance of blue light.

Therefore, the red nanoparticle layer 105R provided at the lower end of the red anode RAN can include nanoparticles each of which has a diameter of 50 to 80 nm, the green nanoparticle layer 105G provided at the lower end of the green anode GAN can include nanoparticles each of which has a diameter of 10 to 20 nm, and the blue nanoparticle layer 105B provided at the lower end of the blue anode BAN can include nanoparticles each of which has a diameter of 5 to 10 nm.

However, as described above, the blue anode BAN can be provided on the upper end surface of the blue reflection electrode 105B.

In this situation, if a blue nanoparticle layer is provided on the upper end surface of the blue reflection electrode 105B, a curvature can be formed on the surface of the blue anode

BAN by the nanoparticles included in the blue nanoparticle layer. Accordingly, light may be refracted on the surface of the blue anode BAN, and thus, the efficiency of light output to the outside may be reduced.

Therefore, a blue nanoparticle layer may not be provided between the blue anode BAN and the blue reflection electrode 105B.

However, if the area of the blue anode BAN is sufficiently large, so that the curvature formed on the surface of the blue anode BAN can be ignored, or the efficiency of light due to the curvature is not significantly reduced, a blue nanoparticle layer can also be provided between the blue anode BAN and the blue reflection electrode 105B.

Hereinafter, for convenience of description, as illustrated in FIGS. 7 and 8, a light emitting display panel without a blue nanoparticle layer between the blue anode BAN and the blue reflection electrode 105B is described as an example of a light emitting display panel 100 applied to a light emitting display apparatus according to an embodiment of the present disclosure.

The nanoparticle layer 106 can be formed by spraying a liquid containing nanoparticles in an inkjet method, for example.

For example, when a liquid containing nanoparticles is sprayed onto the surface of the reflection electrode 105 by using an inkjet method, a nanoparticle layer 106 can be formed on the surface of the reflection electrode 105. Also, when a liquid containing nanoparticles is sprayed onto the surface of a sub-insulation layer composing the insulation layer 104 by using an inkjet method, a nanoparticle layer 106 can be formed on the surface of the sub-insulation layer.

Second, a light emitting display apparatus according to an embodiment of the present disclosure, as described above, includes the insulation layer 104 provided on the planarization layer 103, the nanoparticle layer 106 provided in the insulation layer, and the red anode RAN, the green anode GAN, and the blue anode BAN provided on the insulation layer, and the nanoparticle layer 106 can be provided at a lower end of at least one of the red anode RAN, the green anode GAN, and the blue anode BAN.

Also, a red reflection electrode 105R is provided at the lower end of the red anode RAN, a green reflection electrode 105G is provided at the lower end of the green anode GAN, and a blue reflection electrode 105B is provided at the lower end of the blue anode BAN. The nanoparticle layer 106 can be provided in at least one of a position between the red anode RAN and the red reflection electrode 105R, a position between the green anode GAN and the green reflection electrode 105G, and a position between the blue anode BAN and the blue reflection electrode 105B.

In this situation, the distance between the red anode RAN and the red reflection electrode 105R, the distance between the green anode GAN and the green reflection electrode 105G, and the distance between the blue anode BAN and the blue reflection electrode 105B can be different from each other.

For example, as illustrated in FIGS. 7 and 8, the distance between the red anode RAN and the red reflection electrode 105R can be greater than the distance between the green anode GAN and the green reflection electrode 105G, and the blue anode BAN can be provided on the upper end surface of the blue reflection electrode 105B.

That is, there can be no gap between the blue anode BAN and the blue reflection electrode 105B. For example, the blue reflection electrode 105B can directly contact the blue anode BAN, but embodiments are not limited thereto.

In this situation, the nanoparticle layer 106 can be provided on an upper end surface of at least one of the red reflection electrode 105R, the green reflection electrode 105G, and the blue reflection electrode 105B. For example, a blue nanoparticle layer 106 can be disposed between and directly contact both of the blue reflection electrode 105B and the blue anode BAN, but embodiments are not limited thereto.

For example, as illustrated in FIG. 7, a green nanoparticle layer 106G can be provided only on the green reflection electrode 105G.

That is, when it is determined that the reflectance of the green reflection electrode 105G is less than a preset reflectance range, a green nanoparticle layer 106G can be provided on the green reflection electrode 105G.

The green nanoparticle layer 105G can include nanoparticles each of which has a diameter of 10 to 20 nm (e.g., 15 nm).

On the surface of the nanoparticles provided in the green nanoparticle layer 106G, due to plasma phenomena, the reflectance of light can increase, and accordingly, the light extraction efficiency in the light emitting device ED including the green anode GAN can increase and the green subpixel can be made brighter.

In this situation, as illustrated in FIG. 7, the insulation layer 104 can include a first auxiliary insulation layer 104a and a second auxiliary insulation layer 104b. Also, according to embodiments, the insulation layer 104 can include three or more layers.

Each of the first auxiliary insulation layer 104a and the second auxiliary insulation layer 104b can be formed of at least one organic layer, can be formed of at least one inorganic layer, or can be formed of at least one organic layer and at least one inorganic layer.

Also, the first auxiliary insulation layer 104a and the second auxiliary insulation layer 104b can be formed of the same material.

For example, each of the first auxiliary insulation layer 104a and the second auxiliary insulation layer 104b can be formed of a silicon nitride (SiNx).

For example, as illustrated in FIG. 7, the red reflection electrode 105R can be provided on the planarization layer 103, and the planarization layer 103 and the red reflection electrode 105R can be covered by the first auxiliary insulation layer 104a.

The green reflection electrode 105G can be provided on the first auxiliary insulation layer 104a, and the green nanoparticle layer 106G can be provided on the green reflection electrode 105G.

The green nanoparticle layer 106G and the first auxiliary insulation layer 104a can be covered by the second auxiliary insulation layer 104b.

The blue reflection electrode 105B can be provided on the second auxiliary insulation layer 104b, and a blue anode BAN can be provided on the blue reflection electrode 105B.

A green anode GAN and a red anode RAN can be provided on the second auxiliary insulation layer 104b.

Also, as illustrated in FIG. 8, a red nanoparticle layer 106R can be provided only on the red reflection electrode 105R.

That is, when it is determined that the reflectance of the red reflection electrode 105R is less than a preset reflectance range, a red nanoparticle layer 106R can be provided on the upper end surface of the red reflection electrode 105R.

The red nanoparticle layer 105R can include nanoparticles each of which has a diameter of 50 to 80 nm (e.g., 65 nm).

On the surface of the nanoparticles provided in the red nanoparticle layer 106R, due to plasma phenomena, the reflectance of light can increase, and accordingly, the light extraction efficiency of the light emitting device including the red anode RAN can increase.

In this situation, as illustrated in FIG. 8, the red reflection electrode 105R can be provided on the planarization layer 103, and the red nanoparticle layer 106R can be provided on the red reflection electrode 105R.

The planarization layer 103 and the red nanoparticle layer 106R can be covered by the first auxiliary insulation layer 104a, the green reflection electrode 105G can be provided on the first auxiliary insulation layer 104a, the green reflection electrode 105G and the first auxiliary insulation layer 104a can be covered by the second auxiliary insulation layer 104b, the blue reflection electrode 105B can be provided on the second auxiliary insulation layer 104b, the blue anode BAN can be provided on the blue reflection electrode 105B, and the green anode GAN and the red anode RAN can be provided on the second auxiliary insulation layer 104b.

Also, a nanoparticle layer 106 can be provided on each of the red reflection electrode 105R and the green reflection electrode 105G.

That is, when it is determined that the reflectance of the red reflection electrode 105R and the reflectance of the green reflection electrode 105G are less than a preset reflectance range, a red nanoparticle layer 106R can be provided on the red reflection electrode 105R, and a green nanoparticle layer 106G can be provided on the green reflection electrode 105G.

The red nanoparticle layer 105R can include nanoparticles each of which has a diameter of 50 to 80 nm, and the green nanoparticle layer 105G can include nanoparticles each of which has a diameter of 10 to 20 nm (e.g., 15 nm).

On the surface of the nanoparticles provided in the red nanoparticle layer 106R, due to plasma phenomena, the reflectance of light can increase, and accordingly, the light extraction efficiency of the light emitting device including the red anode RAN can increase and the red subpixels can be made brighter.

Moreover, on the surface of nanoparticles provided in the green nanoparticle layer 106G, due to plasma phenomena, the reflectance of light can increase, and accordingly, the light extraction efficiency of the light emitting device including the green anode GAN can increase and the green subpixels can be made brighter.

In this situation, a red reflection electrode 105R can be provided on the planarization layer 103, and a red nanoparticle layer 106R can be provided on the red reflection electrode 105R.

The planarization layer 103 and the red nanoparticle layer 106R can be covered by the first auxiliary insulation layer 104a, the green reflection electrode 105G can be provided on the first auxiliary insulation layer 104a, and the green nanoparticle layer 106G can be provided on the green reflection electrode 105G.

The green nanoparticle layer 106G and the first auxiliary insulation layer 104a can be covered by the second auxiliary insulation layer 104b, a blue reflection electrode 105B can be provided on the second auxiliary insulation layer 104b, the blue anode BAN can be provided on the blue reflection electrode 105B, and a green anode GAN and a red anode RAN can be provided on the second auxiliary insulation layer 104b.

By the above-described structure, light extraction efficiency in a light emitting device ED including the red anode RAN can be improved, and light extraction efficiency in a light emitting device ED including the green anode GAN can be improved.

Therefore, the luminance of light output from the green pixel G and the red pixel R can be improved.

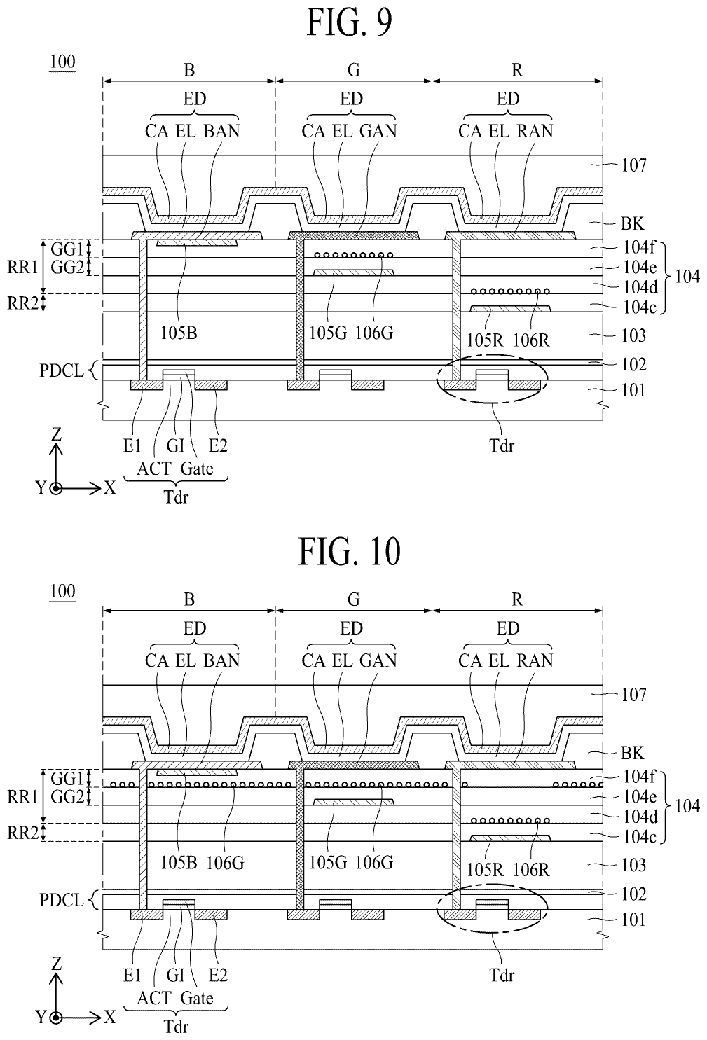

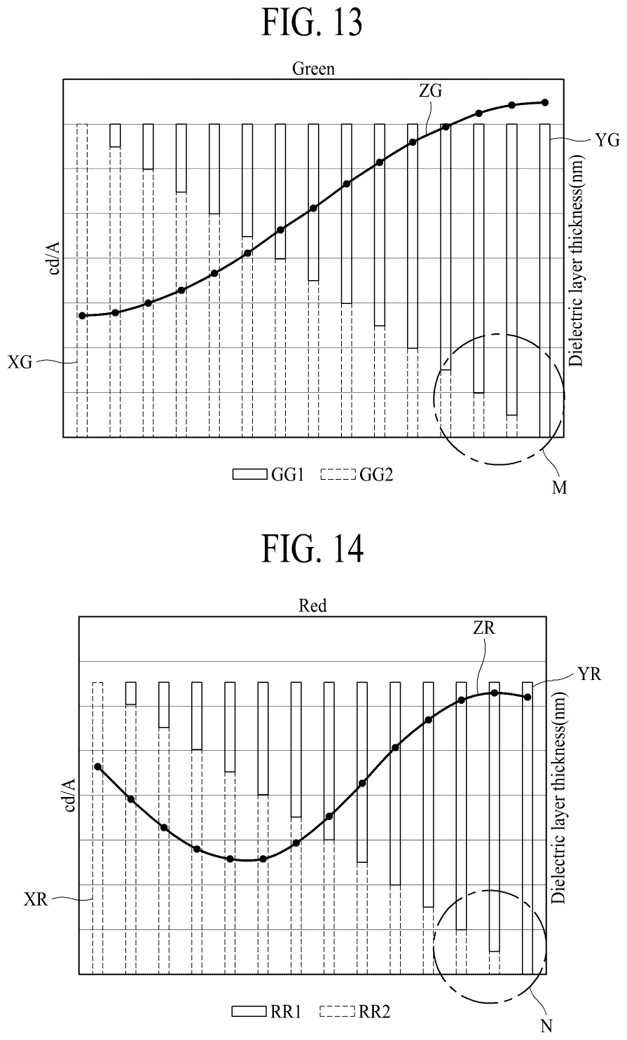

FIGS. 9 to 12 are other example diagrams illustrating cross sections of three pixels applied to a light emitting display apparatus according to an embodiment of the present disclosure, FIG. 13 is an example diagram illustrating a relationship between a position and a reflectance of a green nanoparticle layer applied to a light emitting display apparatus according to an embodiment of the present disclosure, and FIG. 14 is an example diagram illustrating a relationship between a position and a reflectance of a red nanoparticle layer applied to a light emitting display apparatus according to an embodiment of the present disclosure. In the following descriptions, details which are the same as or similar to details described with reference to FIGS. 1 to 8 are omitted or briefly described.

First, in a light emitting display apparatus according to an embodiment of the present disclosure, the distance between the red anode RAN and the red reflection electrode 105R, the distance between the green anode GAN and the green reflection electrode 105G, and the distance between the blue anode BAN and the blue reflection electrode 105B can be different from each other.

For example, as illustrated in FIGS. 9 to 12, the distance between the red anode RAN and the red reflection electrode 105R can be greater than the distance between the green anode GAN and the green reflection electrode 105G, and the blue anode BAN can be provided on an upper end surface of the blue reflection electrode 105B.

That is, there can be no gap between the blue anode BAN and the blue reflection electrode 105B, but embodiments are not limited thereto.

The nanoparticle layer 106 can be provided over at least one of the red reflection electrode 105R, the green reflection electrode 105G, and the blue reflection electrode 105B.

In this situation, the nanoparticle layer 106 is spaced apart from the red reflection electrode 105R, the green reflection electrode 105G, and the blue reflection electrode 105B.

For example, in a light emitting display panel 100 described with reference to FIGS. 7 and 8, the nanoparticle layer 106 can be provided on the upper end surface of at least one of the red reflection electrode 105R, the green reflection electrode 105G, and the blue reflection electrode 105B, and in particular, can be provided on the upper end surface of at least one of the red reflection electrode 105R and the green reflection electrode 105G.

However, in a light emitting display panel 100, which will be described below with reference to FIGS. 9 to 12, the nanoparticle layer 106 is spaced apart from the red reflection electrode 105R, the green reflection electrode 105G, and the blue reflection electrode 105B.

In this situation, the distance between the red nanoparticle layer 106R and the red anode RAN can be different than the distance between the red nanoparticle layer 106R and the red reflection electrode 105R, and the distance between the green nanoparticle layer 106G and the green anode GAN can be different than the distance between the green nanoparticle layer 106G and the green reflection electrode 105G.

Second, for example, as illustrated in FIG. 9, a green nanoparticle layer 106G can be provided between the green anode GAN and the green reflection electrode 105G, and a red nanoparticle layer 106R can be provided between the red anode RAN and the red reflection electrode 105R.

That is, when it is determined that the reflectance of the red reflection electrode 105R and the reflectance of the green reflection electrode 105G are less than a preset reflectance range, a red nanoparticle layer 106R can be provided at an upper end of the red reflection electrode 105R, and a green nanoparticle layer 106G can be provided at an upper end of the green reflection electrode 105G.

The red nanoparticle layer 105R can include nanoparticles each of which has a diameter of 50 to 80 nm (e.g., 65 nm), and the green nanoparticle layer 105G can include nanoparticles each of which has a diameter of 10 to 20 nm (e.g., 15 nm).

On the surface of the nanoparticles provided in the red nanoparticle layer 106R, due to plasma phenomena, the reflectance of light can increase, and accordingly, the light extraction efficiency of the light emitting device including the red anode RAN can increase and the red subpixel can be made brighter.

Also, on the surface of the nanoparticles provided in the green nanoparticle layer 106G, due to plasma phenomena, the reflectance of light can increase, and accordingly, the light extraction efficiency in the light emitting device ED including the green anode GAN can increase and the green subpixel can be made brighter.

In this situation, the insulation layer 104 can include a third auxiliary insulation layer 104c, a fourth auxiliary insulation layer 104d, a fifth auxiliary insulation layer 104c, and a sixth auxiliary insulation layer 104f.

Each of the third auxiliary insulation layer 104c, the fourth auxiliary insulation layer 104d, the fifth auxiliary insulation layer 104e, and the sixth auxiliary insulation layer 104f can be formed of at least one organic layer, at least one inorganic layer, or at least one organic layer and at least one inorganic layer.

Also, the third auxiliary insulation layer 104c, the fourth auxiliary insulation layer 104d, the fifth auxiliary insulation layer 104e, and the sixth auxiliary insulation layer 104f can be formed of the same material.

For example, each of the third auxiliary insulation layer 104c, the fourth auxiliary insulation layer 104d, the fifth auxiliary insulation layer 104c, and the sixth auxiliary insulation layer 104f can be formed of a silicon nitride (SiNx).

For example, as illustrated in FIG. 9, a red reflection electrode 105R can be provided on the planarization layer 103, and the planarization layer 103 and the red reflection electrode 105R can be covered by the third auxiliary insulation layer 104c.

A red nanoparticle layer 106R is provided on the third auxiliary insulation layer 104c, and the third auxiliary insulation layer 104c and the red nanoparticle layer 106R can be covered by the fourth auxiliary insulation layer 104d.

A green reflection electrode 105G can be provided on the fourth auxiliary insulation layer 104d, and the green reflection electrode 105G and the fourth auxiliary insulation layer 104d can be covered by the fifth auxiliary insulation layer 104c.

A green nanoparticle layer 106G can be provided on the fifth auxiliary insulation layer 104c, and the fifth auxiliary insulation layer 104e and the green nanoparticle layer 106G can be covered by the sixth auxiliary insulation layer 104f.

A blue reflection electrode 105B can be provided on the sixth auxiliary insulation layer 104f, and a blue anode BAN can be provided on the blue reflection electrode 105B.

A green anode GAN and a red anode RAN can be provided on the sixth auxiliary insulation layer 104f.

By the above-described structure, light extraction efficiency in a light emitting device including a red anode RAN can be improved, and light extraction efficiency in a light emitting device including a green anode GAN can be improved.

Therefore, the luminance of light output from the red pixel R and the green pixel G can be improved.

In this situation, the distance GG1 between the green anode GAN and the green nanoparticle layer 106G can be greater than the distance GG2 between the green nanoparticle layer 106G and the green reflection electrode 105G. Hereinafter, the distance GG1 can be a thickness of the sixth auxiliary insulation layer 104f, and the distance GG2 can be a thickness of the fifth auxiliary insulation layer 104c.

Also, the distance GG2 between the green nanoparticle layer 106G and the green reflection electrode 105G can be one of 0% to 20% (e.g., 10%) of the distance (GG1+GG2) between the green anode GAN and the green reflection electrode 105G.

Moreover, the distance RR1 between the red anode RAN and the red nanoparticle layer 106R can be greater than the distance RR2 between the red nanoparticle layer 106R and the red reflection electrode 105R. Hereinafter, the distance RR1 can be a thickness of the sixth auxiliary insulation layer 104f, the fifth auxiliary insulation layer 104c, and the fourth auxiliary insulation layer 104d, and the distance RR2 can be a thickness of the third auxiliary insulation layer 104c.

Also, the distance RR2 between the red nanoparticle layer 106R and the red reflection electrode 105R can be any one of 0% to 15% (e.g., 7.5%) of the distance RR1+RR2 between the red anode RAN and the red reflection electrode 105R.

The ratio of the distances as described above can be set through various tests and simulations.

For example, FIG. 13 is an example diagram illustrating a change in luminous intensity according to a ratio of the distance GG2 between the green nanoparticle layer 106G and the green reflection electrode 105G illustrated in FIG. 9 and the distance GG1 between the green anode GAN and the green nanoparticle layer 106G.

That is, FIG. 13 is an example diagram illustrating a change in luminous intensity of light output from a light emitting device ED including a green anode GAN when the thickness GG2 of the fifth auxiliary insulation layer 104e and the thickness GG1 of the sixth auxiliary insulation layer 104f illustrated in FIG. 9 are varied. In FIG. 13, the dotted bar XG represents the thickness GG2 of the fifth auxiliary insulation layer 104e, the solid bar YG represents the thickness GG1 of the sixth auxiliary insulation layer 104f, and the curved graph ZG represents the luminous intensity of green light.

For example, referring to FIG. 13, as the length of the dotted bar XG decreases and the length of the solid bar YG increases, the luminous intensity ZG increases.

This means that as the thickness GG2 of the fifth auxiliary insulation layer 104c decreases and the thickness GG1 of the sixth auxiliary insulation layer 104f increases, the luminous intensity ZG increases.

In particular, according to FIG. 13, when the distance GG2 between the green nanoparticle layer 106G and the green reflection electrode 105G is included in the range M of 0% to 20% of the distance (GG1+GG2) between the green anode GAN and the green reflection electrode 105G, the luminous intensity ZG is high.

This means that when the thickness GG2 of the fifth auxiliary insulation layer 104e is included in the range M of 0% to 20% of the thickness (GG1+GG2) of the fifth auxiliary insulation layer 104c and the sixth auxiliary insulation layer 104f, the luminous intensity ZG is high.

Also, FIG. 14 is an example diagram illustrating a change in luminous intensity according to a ratio of the distance RR2 between the red nanoparticle layer 106R and the red reflection electrode 105R illustrated in FIG. 9 and the distance RR1 between the red anode RAN and the red nanoparticle layer 106R.

FIG. 14 is an example diagram illustrating a change in luminous intensity of light output from a light emitting device ED including a red anode RAN when the thickness RR2 of the third auxiliary insulation layer 104c and the thickness RR1 of the fourth auxiliary insulation layer 104d illustrated in FIG. 9 are varied. In FIG. 14, the dotted bar XR represents the thickness RR2 of the third auxiliary insulation layer 104c, the solid bar YR represents the thickness RR1 of the fourth auxiliary insulation layer 104d, and the curved graph ZR represents the luminous intensity of red light.

For example, referring to FIG. 14, as the length of the dotted bar XR decreases and the length of the solid bar YR increases, the luminous intensity ZR increases.

This means that as the thickness RR2 of the third auxiliary insulation layer 104c decreases and the thickness RR1 of the fourth auxiliary insulation layer 104d increases, the luminous intensity ZR increases.

In particular, according to FIG. 14, when the distance RR2 between the red nanoparticle layer 106R and the red reflection electrode 105R is included in the range N of 0% to 15% of the distance (RR1+RR2) between the red anode RAN and the red reflection electrode 105R, the luminous intensity is high.

This means that when the thickness RR2 of the third auxiliary insulation layer 104c is included in the range N of 0% to 15% of the thickness (RR1+RR2) of the third auxiliary insulation layer 104c and the fourth auxiliary insulation layer 104d, the luminous intensity ZR is high.

Therefore, in a light emitting display panel 100 illustrated in FIG. 9, the distance GG1 between the green anode GAN and the green nanoparticle layer 106G, the distance GG2 between the green nanoparticle layer 106G and the green reflection electrode 105G, the distance RR1 between the red anode RAN and the red nanoparticle layer 106R, and the distance RR2 between the red nanoparticle layer 106R and the red reflection electrode 105R can be variously set using the graphs illustrated in FIGS. 13 and 14.

In the above, a light emitting display panel 100 provided with a green nanoparticle layer 106G between the green anode GAN and the green reflection electrode 105G and a red nanoparticle layer 106R between the red anode RAN and the red reflection electrode 105R has been described.

However, in a light emitting display panel 100 applied to a light emitting display apparatus according to an embodiment of the present disclosure, a green nanoparticle layer 106G can be provided only between the green anode GAN and the green reflection electrode 105G, and a nanoparticle layer can not be provided between the red anode RAN and the red reflection electrode 105R and between the blue anode BAN and the blue reflection electrode 105B.

Also, in a light emitting display panel 100 applied to a light emitting display apparatus according to an embodiment of the present disclosure, a red nanoparticle layer 106R can be provided only between the red anode RAN and the red reflection electrode 105R, and a nanoparticle layer may not be provided between the green anode GAN and the green reflection electrode 105G nor between the blue anode BAN and the blue reflection electrode 105B, but embodiments are not limited thereto.

Hereinafter, a light emitting display panel 100 illustrated in FIGS. 10 to 12 will be described. In the following descriptions, details which are the same as or similar to details described with reference to FIG. 9 will be omitted or briefly described.

Third, a green nanoparticle layer 106G illustrated in FIG. 9 can extend to a lower end of the blue reflection electrode 105B, as illustrated in FIG. 10.

As described above, a light emitting display panel 100 applied to a light emitting display apparatus according to an embodiment of the present disclosure can include a substrate 101 provided with a semiconductor, and can be applied to a small electronic device such as a virtual reality (VR) device and an augmented reality (AR) device.

In this situation, an area of a pixel P and a distance between pixels P are smaller than an area of a pixel and a distance between pixels in a light emitting display panel using a glass substrate and a plastic substrate.

Therefore, when the green nanoparticle layer 106G, as illustrated in FIG. 9, is provided between the green anode GAN and the green reflection electrode 105G and the red nanoparticle layer 106R is provided between the red anode RAN and the red reflection electrode 105R, the green nanoparticle layer 106G can extend to a lower end of the blue reflection electrode 105B, as illustrated in FIG. 10. In this situation, the green nanoparticle layer 106G can be patterned so that it does not overlap with the red reflection electrode 105R or the red nanoparticle layer 106R.

To provide an additional description, the green nanoparticle layer 106G extending to the lower end of the blue reflection electrode 105B has no effect on the blue pixel B. In other words, the green nanoparticle layer 106G can extend across both the green pixel G and the blue pixel B, but does not affect the blue pixel B, which can improve or simplify manufacturing of the device.

However, if the green nanoparticle layer 106G overlaps with the red reflection electrode 105R or the red nanoparticle layer 106R, light reflected from the red reflection electrode 105R or the red nanoparticle layer 106R can be affected by the green nanoparticle layer 106G. Accordingly, the green nanoparticle layer 106G can be patterned so that it does not overlap with the red reflection electrode 105R or the red nanoparticle layer 106R.

The process of preventing the green nanoparticle layer 106G from overlapping with just the red reflection electrode 105R can be simpler or more efficient than the process of preventing the green nanoparticle layer 106G from overlapping with both of the red reflection electrode 105R and the blue reflection electrode 105B.

Therefore, the manufacturing process of a light emitting display panel illustrated in FIG. 10 can be simpler and more efficient than the manufacturing process of a light emitting display panel illustrated in FIG. 9, manufacturing time and defects can be reduced and yields can be improved.

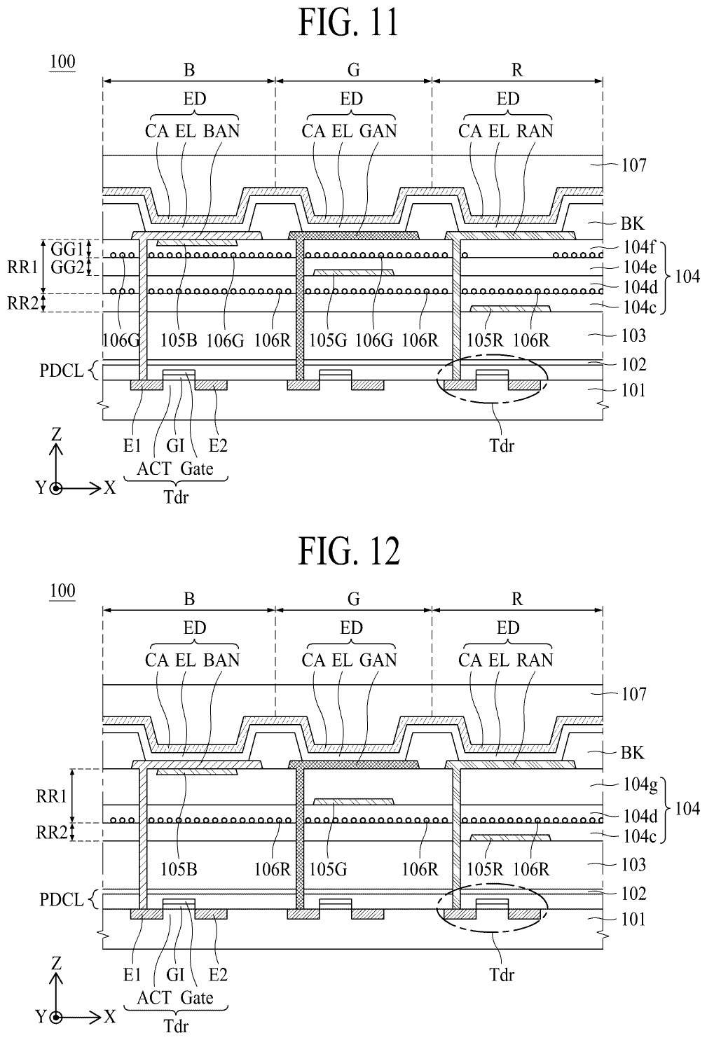

Fourth, the red nanoparticle layer 106R illustrated in FIG. 9 or the red nanoparticle layer 106R illustrated in FIG. 10 can extend to the lower ends of the green reflection electrode 105G and the blue reflection electrode 105B, as illustrated in FIG. 11. In other words, the red nanoparticle layer 106R can extend across the blue, green and red subpixels, which can improve manufacturing time and reduce costs.

For example, when a green nanoparticle layer 106G is provided between the green anode GAN and the green reflection electrode 105G and a red nanoparticle layer 106R is provided between the red anode RAN and the red reflection electrode 105R, the red nanoparticle layer 106R can extend to the lower end of the blue reflection electrode 105B and the lower end of the green reflection electrode 105G, as illustrated in FIG. 11. In this situation, the red nanoparticle layer 106R can overlap with the green reflection electrode 105G and the blue reflection electrode 105B.

However, the red nanoparticle layer 106R extending to the lower ends of the blue reflection electrode 105B and the green reflection electrode 105G has no effect on the blue pixel B and the green pixel G.

Therefore, the red nanoparticle layer 106R can be provided on the entire upper end surface of the third auxiliary insulation layer 104c.

Therefore, the manufacturing process of a light emitting display panel illustrated in FIG. 11 can be simpler and more efficient than the manufacturing process of a light emitting display panel illustrated in FIGS. 9 and 10.

Fifth, as illustrated in FIG. 12, when the red nanoparticle layer 106R is provided between the red anode RAN and the red reflection electrode 105R, the red nanoparticle layer 106R can extend to the lower ends of the blue reflection electrode 105B and the green reflection electrode 105G.

For example, as illustrated in FIG. 12, when a red nanoparticle layer 106R is provided only between the red anode RAN and the red reflection electrode 105R and no nanoparticle layer is provided between the green anode GAN and the green reflection electrode 105G and between the blue anode BAN and the blue reflection electrode 105B, the red nanoparticle layer 106R can extend to the lower end of the blue reflection electrode 105B and the lower end of the green reflection electrode 105G. In this situation, the red nanoparticle layer 106G can overlap with the green reflection electrode 105R and the blue reflection electrode 105B.

However, the red nanoparticle layer 106R extending to the lower ends of the blue reflection electrode 105B and the green reflection electrode 105G has no effect on the blue pixel B and the green pixel G. Accordingly, the red nanoparticle layer 106R can be provided on the entire upper end surface of the third auxiliary insulation layer 104c.

To provide an additional description, when it is determined that the reflectance of a red reflection electrode 105R is less than a preset reflectance range, and thus the luminance of the light output from the red pixel R is less than the luminance of the light output from the green pixel G and the blue pixel B, the red nanoparticle layer 106R can be provided only on the red reflection electrode 105R, as illustrated in FIG. 12.

Also, when it is difficult to pattern a green nanoparticle layer 106G in the form illustrated in FIGS. 9 to 11, the red nanoparticle layer 106R can be provided only on the red reflection electrode 105R, as illustrated in FIG. 12.

Therefore, the manufacturing process of a light emitting display panel illustrated in FIG. 12 can be simpler and more efficient than the manufacturing process of a light emitting display panel illustrated in FIGS. 9 to 11.

The features of the light emitting display apparatus according to an embodiment of the present disclosure are briefly summarized as follows.

A light emitting display apparatus according to an embodiment of the present disclosure includes a substrate, a planarization layer configured to cover a pixel driving circuit layer provided on the substrate, an insulation layer configured to be provided on the planarization layer, a nanoparticle layer configured to be provided in the insulation layer, and a first anode, a second anode, and a third anode configured to be provided on the insulation layer, in which the nanoparticle layer is provided at a lower end of at least one of the first anode, the second anode, and the third anode.

A first reflection electrode is provided at a lower end of the first anode, a second reflection electrode is provided at a lower end of the second anode, and a third reflection electrode is provided at a lower end of the third anode, and the nanoparticle layer is provided in at least one of a position between the red anode RAN and the red reflection electrode 105R, a position between the green anode GAN and the green reflection electrode 105G, and a position between the blue anode BAN and the blue reflection electrode 105B.

A diameter of a nanoparticle included in a nanoparticle layer provided at a lower end of the first anode, a diameter of a nanoparticle included in a nanoparticle layer provided at a lower end of the second anode, and a diameter of a nanoparticle included in a nanoparticle layer provided at a lower end of the third anode are different from each other.

A distance between the first anode and the first reflection electrode, a distance between the second anode and the second reflection electrode, and a distance between the third anode and the third reflection electrode are different from each other, and the nanoparticle layer is provided on an upper end surface of at least one of the first reflection electrode, the second reflection electrode, and the third reflection electrode.

The insulation layer includes a first auxiliary insulation layer and a second auxiliary insulation layer, the first reflection electrode is provided on the planarization layer, the planarization layer and the first reflection electrode are covered by the first auxiliary insulation layer, the second reflection electrode is provided on the first auxiliary insulation layer, a second nanoparticle layer is provided on the second reflection electrode, the second nanoparticle layer and the first auxiliary insulation layer are covered by the second auxiliary insulation layer, the third reflection electrode is provided on the second auxiliary insulation layer, the third anode is provided on the third reflection electrode, and the second anode and the first anode are provided on the second auxiliary insulation layer.

A distance between the first anode and the first reflection electrode, a distance between the second anode and the second reflection electrode, and a distance between the third anode and the third reflection electrode are different from each other. The nanoparticle layer is provided over at least one of the first reflection electrode, the second reflection electrode, and the third reflection electrode, and the nanoparticle layer is spaced apart from the first reflection electrode, the second reflection electrode, and the third reflection electrode.

A second nanoparticle layer is provided between the second anode and the second reflection electrode, and a first nanoparticle layer is provided between the first anode and the first reflection electrode.

The insulation layer includes a third auxiliary insulation layer, a fourth auxiliary insulation layer, a fifth auxiliary insulation layer, and a sixth auxiliary insulation layer, the first reflection electrode is provided on the planarization layer, the planarization layer and the first reflection electrode are covered by the third auxiliary insulation layer, the first nanoparticle layer is provided on the third auxiliary insulation layer, the third auxiliary insulation layer and the first nanoparticle layer are covered by the fourth auxiliary insulation layer, the second reflection electrode is provided on the fourth auxiliary insulation layer, the second reflection electrode and the fourth auxiliary insulation layer are covered by the fifth auxiliary insulation layer, the second nanoparticle layer is provided on the fifth auxiliary insulation layer, the fifth auxiliary insulation layer and the second nanoparticle layer are covered by the sixth auxiliary insulation layer, the third reflection electrode is provided on the sixth auxiliary insulation layer, the third anode is provided on the third reflection electrode, and the second anode and the first anode are provided on the sixth auxiliary insulation layer.

A distance between the second anode and the second nanoparticle layer is greater than a distance between the second nanoparticle layer and the second reflection electrode.

A distance between the second nanoparticle layer and the second reflection electrode is any one of 0% to 20% (e.g., 10%) of a distance between the second anode and the second reflection electrode.

A distance between the first anode and the first nanoparticle layer is greater than a distance between the first nanoparticle layer and the first reflection electrode.

A distance between the first nanoparticle layer and the first reflection electrode is any one of 0% to 15% (e.g., 7.5%) of a distance between the first anode and the first reflection electrode.

The second nanoparticle layer extends to a lower end of the third reflection electrode.

The first nanoparticle layer extends to lower ends of the third reflection electrode and the second reflection electrode.

A first nanoparticle layer is provided between the first anode and the first reflection electrode, and the first nanoparticle layer extends to lower ends of the third reflection electrode and the second reflection electrode.

The first anode is an anode provided in a red pixel, the second anode is an anode provided in a green pixel, and the third anode is an anode provided in a blue pixel.

The light emitting display apparatus according to an embodiment of the present disclosure can be applied to all electronic devices including a light emitting display panel. For example, the light emitting display apparatus according to the present disclosure can be applied to a virtual reality (VR) device, an augmented reality (AR) device, a mobile device, a video phone, a smart watch, a watch phone, or a wearable device, foldable device, rollable device, bendable device, flexible device, curved device, electronic notebook, e-book, PMP (portable multimedia player), PDA (personal digital assistant), MP3 player, mobile medical device, desktop PC, laptop PC, netbook computer, workstation, navigation, car navigation, vehicle display devices, televisions, wall paper display devices, signage devices, game devices, laptops, monitors, cameras, camcorders, and home appliances.

According to a light emitting display apparatus according to an embodiment of the present disclosure, a reflection electrode and nanoparticles can be provided in an insulation layer at a lower end of an anode.

The reflection electrode can reflect light generated from a light emitting layer on the anode, and the frequency band of light can be adjusted by an optical distance between the reflection electrode and the anode.

Moreover, the nanoparticles can efficiently reflect light generated in the light emitting layer by using the plasmon phenomenon, and accordingly, the amount of light output in the cathode direction can be increased.

Therefore, according to a light emitting display apparatus according to an embodiment of the present disclosure, power consumption can be reduced.

That is, a light emitting display apparatus according to an embodiment of the present disclosure can output an image having a greater luminance than the prior art even when driven at low power.

Also, because the location of nanoparticles can be determined for each pixel through various tests and simulations, the luminance of each pixel can be efficiently improved.

Therefore, according to a light emitting display apparatus according to an embodiment of the present disclosure, the amount of light reflected from a lower end of the anode toward the cathode can increase, and accordingly, the luminance of light output from the pixel can increase.

As the luminance of light output from the pixel increases, the quality of a light emitting display apparatus can be improved.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

What is claimed is:

1. A light emitting display apparatus comprising:
a pixel driving circuit layer disposed on a substrate;
a planarization layer disposed on the pixel driving circuit layer;
an insulation layer disposed on the planarization layer;
a nanoparticle layer disposed in the insulation layer; and
a first anode, a second anode, and a third anode disposed on the insulation layer,
wherein the nanoparticle layer is disposed under at least one of the first anode, the second anode and the third anode.

2. The light emitting display apparatus of claim 1, wherein a first reflection electrode is disposed under the first anode, a second reflection electrode is disposed under the second anode, and a third reflection electrode is disposed under the third anode, and
wherein the nanoparticle layer is disposed between the first anode and the first reflection electrode, between the second anode and the second reflection electrode, or between the third anode and the third reflection electrode.

3. The light emitting display apparatus of claim 2, wherein a distance between the first anode and the first reflection electrode, a distance between the second anode and the second reflection electrode, and a distance between the third anode and the third reflection electrode are different from each other, and
wherein the nanoparticle layer is disposed on an upper surface of at least one of the first reflection electrode, the second reflection electrode, and the third reflection electrode.

4. The light emitting display apparatus of claim 3, wherein the insulation layer includes a first auxiliary insulation layer and a second auxiliary insulation layer,
wherein the first reflection electrode is disposed on the planarization layer,
wherein the planarization layer and the first reflection electrode are covered by the first auxiliary insulation layer,
wherein the second reflection electrode is disposed on the first auxiliary insulation layer,
wherein a second nanoparticle layer is disposed on the second reflection electrode,
wherein the second nanoparticle layer and the first auxiliary insulation layer are covered by the second auxiliary insulation layer,
wherein the third reflection electrode is disposed on the second auxiliary insulation layer,
wherein the third anode is disposed on the third reflection electrode, and
wherein the second anode and the first anode are disposed on the second auxiliary insulation layer.

5. The light emitting display apparatus of claim 2, wherein a first distance between the first anode and the first reflection electrode, a second distance between the second anode and the second reflection electrode, and a third distance between the third anode and the third reflection electrode are different from each other,
wherein the nanoparticle layer is provided on at least one of the first reflection electrode, the second reflection electrode, and the third reflection electrode, and
wherein the nanoparticle layer is spaced apart from the first reflection electrode, the second reflection electrode, and the third reflection electrode.

6. The light emitting display apparatus of claim 5, wherein a first nanoparticle layer is disposed between the first anode and the first reflection electrode, and a second nanoparticle layer is disposed between the second anode and the second reflection electrode.

7. The light emitting display apparatus of claim 6, wherein the insulation layer includes a third auxiliary insulation layer, a fourth auxiliary insulation layer, a fifth auxiliary insulation layer, and a sixth auxiliary insulation layer,
wherein the first reflection electrode is disposed on the planarization layer,
wherein the planarization layer and the first reflection electrode are covered by the third auxiliary insulation layer,
wherein the first nanoparticle layer is disposed on the third auxiliary insulation layer, wherein the third auxiliary insulation layer and the first nanoparticle layer are covered by the fourth auxiliary insulation layer,
wherein the second reflection electrode is disposed on the fourth auxiliary insulation layer,
wherein the second reflection electrode and the fourth auxiliary insulation layer are covered by the fifth auxiliary insulation layer,
wherein the second nanoparticle layer is disposed on the fifth auxiliary insulation layer,
wherein the fifth auxiliary insulation layer and the second nanoparticle layer are covered by the sixth auxiliary insulation layer,
wherein the third reflection electrode is disposed on the sixth auxiliary insulation layer,
wherein the third anode is disposed on the third reflection electrode, and
wherein the second anode and the first anode are disposed on the sixth auxiliary insulation layer.

8. The light emitting display apparatus of claim 6, wherein a distance between the second anode and the second nanoparticle layer is greater than a distance between the second nanoparticle layer and the second reflection electrode.

9. The light emitting display apparatus of claim 6, wherein a distance between the second nanoparticle layer and the second reflection electrode is any one of 0% to 20% of a distance between the second anode and the second reflection electrode.

10. The light emitting display apparatus of claim 6, wherein a distance between the first anode and the first nanoparticle layer is greater than a distance between the first nanoparticle layer and the first reflection electrode.

11. The light emitting display apparatus of claim 6, wherein a distance between the first nanoparticle layer and the first reflection electrode is any one of 0% to 15% of a distance between the first anode and the first reflection electrode.

12. The light emitting display apparatus of claim 6, wherein the second nanoparticle layer extends across the third reflection electrode.

13. The light emitting display apparatus of claim 6, wherein the first nanoparticle layer overlaps with the third reflection electrode and the second reflection electrode.

14. The light emitting display apparatus of claim 5, wherein a first nanoparticle layer is disposed between the first anode and the first reflection electrode, and
wherein the first nanoparticle layer extends across or overlaps with the third reflection electrode and the second reflection electrode.

15. The light emitting display apparatus of claim 1, wherein a first diameter of a first nanoparticle under the first anode, a second diameter of a second nanoparticle under the second anode, and a third diameter of a third nanoparticle under the third anode are different from each other.

16. The light emitting display apparatus of claim 1, wherein the first anode is an anode in a red sub-pixel, the second anode is an anode in a green sub-pixel, and the third anode is an anode in a blue sub-pixel.

17. A light emitting display apparatus comprising:
a first sub-pixel, a second sub-pixel and a third sub-pixel disposed on a substrate, the first, second and third sub-pixels including first, second and third anodes, respectively;
a first reflection electrode disposed under the first anode of the first sub-pixel;
a second reflection electrode disposed under the second anode of the second sub-pixel;
a third reflection electrode disposed under the third anode of the third sub-pixel; and
a nanoparticle layer disposed between the first reflection electrode and the first anode, between the second reflection electrode and the second anode, or between the third reflection electrode and the third anode.

18. The light emitting display apparatus of claim 17, wherein the nanoparticle layer includes a plurality of metal nanoparticles.

19. The light emitting display apparatus of claim 17, wherein the nanoparticle layer includes a first nanoparticle layer and a second nanoparticle layer, and
wherein the first nanoparticle layer is located at a first distance away from the substrate, and the second nanoparticle layer is located at a second distance away from the substrate, the second distance being different than the first distance.

20. The light emitting display apparatus of claim 17, wherein the nanoparticle layer includes a first nanoparticle layer including a first plurality of nanoparticles disposed between the third reflection electrode and the third anode, and a second nanoparticle layer including a second plurality of nanoparticles disposed between the second reflection electrode and the second anode, and
wherein sizes of the first plurality of nanoparticles are greater than sizes of the second plurality of nanoparticles.

21. The light emitting display apparatus of claim 17, wherein the nanoparticle layer includes a first nanoparticle layer including a first plurality of nanoparticles, and a second nanoparticle layer including a second plurality of nanoparticles, and
wherein at least one of the first, second and third reflection electrodes is disposed between the first nanoparticle layer and the second nanoparticle layer.
